(19) United States
(12) Patent Application Publication
(10) Pub. No.: US 2015/0371754 A1
(43) Pub. Date: Dec. 24, 2015

(54) MULTILAYER INDUCTOR, AND BOARD HAVING THE SAME

(71) Applicant: SAMSUNG ELECTRO-MECHANICS CO., LTD., Suwon-Si (KR)

(72) Inventors: Jeong Hwan IM, Suwon-Si (KR); Young Jin Ha, Suwon-Si (KR)

(73) Assignee: SAMSUNG ELECTRO-MECHANICS CO., LTD.

(21) Appl. No.: 14/504,084

(22) Filed: Oct. 1, 2014

(30) Foreign Application Priority Data
Jun. 24, 2014 (KR) 10-2014-0077566

(51) Int. Cl. H01F 27/28; H05K 1/18

(52) U.S. Cl. CPC H01F 27/2804; H05K 1/181; H01F 2027/2809

(57) ABSTRACT

A multilayer inductor may include: a multilayer body including a plurality of insulation layers stacked therein and having a thickness greater than a width thereof; and an internal coil part formed in the multilayer body by electrically connecting a plurality of internal coil patterns disposed on the plurality of insulation layers. The internal coil part may be disposed to be biased toward one portion of the multilayer body from a central portion of the multilayer body in a thickness direction.

### CROSS-REFERENCE TO RELATED APPLICATION

This application claims the benefit of Korean Patent Application No. 10-2014-0077566 filed on Jun. 24, 2014, with the Korean Intellectual Property Office, the disclosure of which is incorporated herein by reference.

### BACKGROUND

The present disclosure relates to a multilayer inductor and a board having the same.

An inductor, which is one of the chip electronic components, is a representative passive element forming an electronic circuit together with a resistor and a capacitor to remove noise. Such an inductor is combined with the capacitor using electromagnetic characteristics to configure a resonance circuit amplifying a signal in a specific frequency band, a filter circuit, or the like.

In general, an inductor may include a multilayer body formed of a magnetic material or an insulative material, an internal coil part formed in the multilayer body, and an external electrode installed on a surface of the multilayer body so as to be connected to the internal coil part.

The inductor may be mounted on a board to be used. At the time of mounting the inductor on the board, the inductor may be electrically connected to a mounting pad on a board through soldering, and the mounting pad may be connected to other external circuits through wiring patterns or conductive vias in the board.

In the case in which the inductor is improperly aligned and mounted on the board, a mounting defect may occur, and a short-circuit due to contact with an electronic component adjacent to the inductor may occur.

### RELATED ART DOCUMENT

(Patent Document 1) Korean Patent Laid-Open Publication No. 2011-0128554

### SUMMARY

An exemplary embodiment in the present disclosure may provide a multilayer inductor and a board having the same.

According to an exemplary embodiment in the present disclosure, a multilayer inductor may include: a multilayer body including a plurality of insulation layers stacked therein and having a thickness greater than a width thereof; and an internal coil part formed in the multilayer body by electrically connecting a plurality of internal coil patterns disposed on the plurality of insulation layers, wherein the internal coil part is disposed to be biased toward one portion of the multilayer body from a central portion of the multilayer body in a thickness direction.

According to an exemplary embodiment in the present disclosure, a board having a multilayer inductor, the board including: a printed circuit board having first and second electrode pads formed thereon; and a multilayer inductor mounted on the printed circuit board, wherein the multilayer inductor includes a multilayer body including a plurality of insulation layers stacked therein and having a thickness larger than a width thereof; and an internal coil part formed in the multilayer body by electrically connecting a plurality of internal coil patterns disposed on the plurality of insulation layers, the internal coil part being disposed to be biased toward one portion of the multilayer body from a central portion of the multilayer body in a thickness direction.

### BRIEF DESCRIPTION OF DRAWINGS

The above and other aspects, features and other advantages in the present disclosure will be more clearly understood from the following detailed description taken in conjunction with the accompanying drawings, in which:

FIG. 1 is a partially cut-away perspective view of a multilayer inductor according to an exemplary embodiment in the present disclosure;

FIG. 2 is an exploded perspective view of a multilayer body, a component of the multilayer inductor according to an exemplary embodiment in the present disclosure;

FIG. 3 is a cross-sectional view taken along line A-A′ of FIG. 1;

FIG. 4 is a partially cut-away perspective view of a modified example of the multilayer inductor according to an exemplary embodiment in the present disclosure;

FIG. 5 is an exploded perspective view of a multilayer body, a component of the multilayer inductor in the modified example of FIG. 4;

FIG. 6 is a cross-sectional view taken along line B-B′ of FIG. 4;

FIG. 7 is a partially cut-away perspective view schematically showing a multilayer inductor mounted on a board according to an exemplary embodiment in the present disclosure; and

FIG. 8 is a partially cut-away perspective view schematically showing a multilayer inductor mounted on a modified example of the board according to another exemplary embodiment in the present disclosure.

### DETAILED DESCRIPTION

Exemplary embodiments in the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

Multilayer Inductor

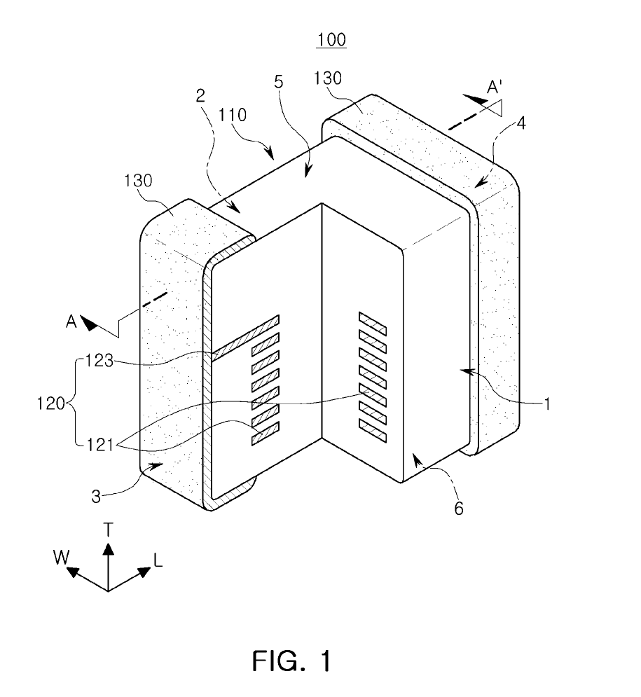

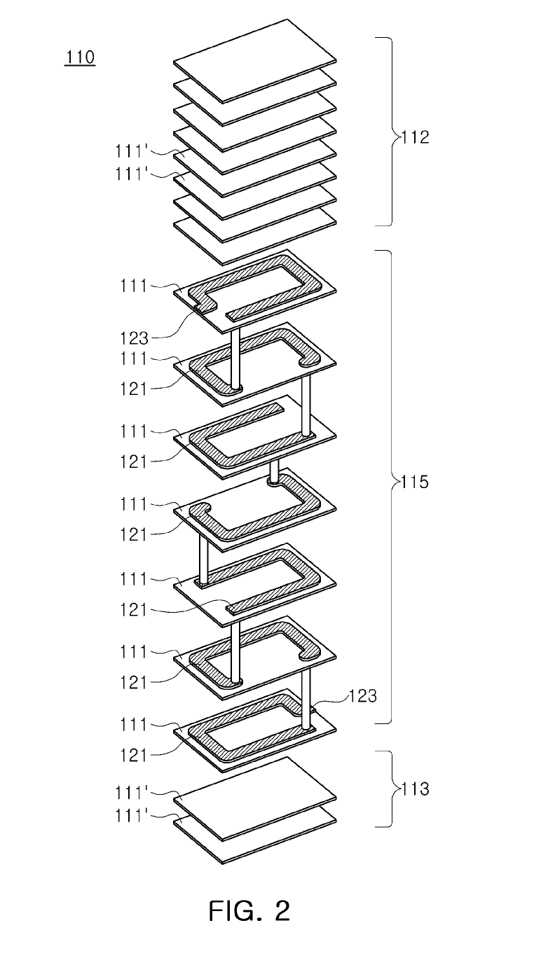

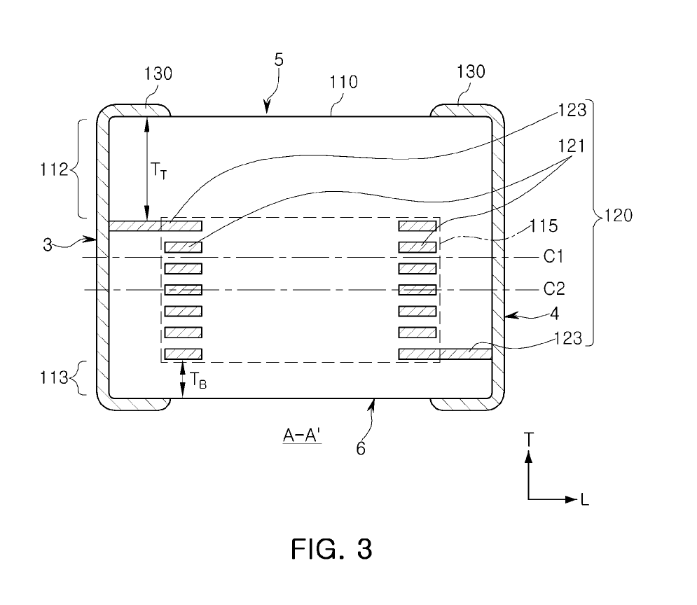

FIG. 1 is a perspective view of a multilayer inductor 100 according to an exemplary embodiment in the present disclosure, and FIG. 2 is an exploded perspective view of a multilayer body 110, is a component of the multilayer inductor according to an exemplary embodiment in the present disclosure. FIG. 3 is a cross-sectional view taken along line A-A′ of FIG. 1.

Referring to FIGS. 1 and 2, the multilayer inductor 100 according to an exemplary embodiment in the present disclosure may include a multilayer body 110, an internal coil part 120, and external electrodes 130.

The multilayer body 110 may be formed by stacking a plurality of insulation layers 111 and 111′, and a shape and a dimension of the multilayer body and the number of stacked insulation layers are not limited to those shown in the present exemplary embodiment.

The plurality of insulation layers 111 and 111′ forming the multilayer body 110 may be in a sintered state, and adjacent insulation layers are integrated with each other so that boundaries therebetween are not readily apparent.

The multilayer body 110 may have a hexahedral shape, and directions of the hexahedron will be defined in order to clearly describe the exemplary embodiment in the present disclosure. L, W and T shown in FIG. 1 refer to a length direction, a width direction, and a thickness direction, respectively.

In the present exemplary embodiment, for convenience of explanation, two surfaces of the multilayer body 110 opposing each other in the thickness direction may be defined as upper and lower surfaces 5 and 6, and two surfaces connecting the upper and lower surfaces to each other and opposing each other in the width direction may be defined as first and second side surfaces 1 and 2, and two surfaces vertically intersecting with the first and second side surfaces 1 and 2 and opposing each other in the length direction may be defined as first and second end surfaces 3 and 4.

The multilayer body 110 may contain Mn—Zn based ferrite, Ni—Zn based ferrite, Ni—Zn—Cu based ferrite, Mn—Mg based ferrite, Ba based ferrite, or Li based ferrite, but is not limited thereto. That is, the multilayer body 110 may contain various magnetic materials known in the art.

Internal coil patterns 121 for forming the internal coil part 120 may be formed on one surfaces of the plurality of insulation layers 111, and conductive vias for electrically connecting the coil patterns may be formed to penetrate through the insulation layers in the thickness direction.

Therefore, one end portions of the internal coil patterns 121 formed on the respective insulation layers 111 may be electrically connected to each other through the conductive vias formed in the insulation layers adjacent to each other, thereby forming the internal coil part 120.

The internal coil patterns 121 may be formed by printing a conductive paste containing a conductive metal on the plurality of insulation layers 111 forming the multilayer body 110 at a predetermined thickness.

Conductive vias may be formed in predetermined positions in the respective insulation layers on which the internal coil patterns 121 are printed, and the internal coil patterns 121 formed on the respective insulation layers may be electrically connected to each other through the conductive vias, thereby forming a single internal coil part.

The conductive metal forming the internal coil patterns 121 is not particularly limited as long as it has excellent electrical conductivity. For example, as the conductive metal, silver (Ag), palladium (Pd), aluminum (Al), nickel (Ni), titanium (Ti), gold (Au), copper (Cu), platinum (Pt), or the like, may be used alone, or a mixture thereof may be used. In consideration of improving electrical conductivity and decreasing a manufacturing cost, most preferably, copper (Cu) may be used.

Among the plurality of internal coil patterns 121 forming the internal coil part 120, two internal coil patterns may respectively include lead-out portion 123 exposed to the outside of the multilayer body so as to be connected to the external electrodes.

The insulation layers 111′ on which the internal coil patterns are not disposed may be disposed on one surface and the other surface of the insulation layers 111 on which the internal coil patterns are disposed in a stacking direction.

FIG. 3 is a cross-sectional view taken along line A-A′ of FIG. 1.

Referring to FIGS. 2 and 3, according to an exemplary embodiment in the present disclosure, the internal coil patterns 121 may be stacked in the thickness direction of the multilayer body 110.

In this case, the insulation layers 111′ on which the internal coil patterns 121 are not formed may be disposed on upper and lower surfaces of an active part 115 including the internal coil patterns to form inductance, thereby forming upper and lower cover parts 112 and 113.

According to an exemplary embodiment in the present disclosure, the internal coil part 120 may be disposed to be biased toward one portion of the multilayer body 110 in the thickness direction, and the upper cover part 112 may have a thickness greater than that of the lower cover part 113.

The external electrodes 130 may be formed on external surfaces of the multilayer body 110 to be connected to the lead-out portions 123 of the internal coil part 120 exposed to the outside of the multilayer body 110.

For example, the external electrodes 130 may be formed on the first and second end surfaces 3 and 4 of the multilayer body 110 and extended to the upper and lower surfaces of the multilayer body 110 in the thickness direction and/or the first and second side surfaces thereof in the width direction.

The external electrodes 130 may contain a metal having excellent electrical conductivity. For example, the external electrodes 130 may be formed of one of nickel (Ni), copper (Cu), tin (Sn), silver (Ag), and the like, an alloy thereof, or the like.

Again, referring to FIG. 1, in the multilayer inductor according to an exemplary embodiment in the present disclosure, in order to implement high inductance, a width and a thickness of the multilayer body 110 are set such that they may not be substantially equal to each other. The multilayer inductor may be set such that a thickness (T) of the multilayer body 110 is larger than a width (W) of the multilayer body 110.

According to an exemplary embodiment in the present disclosure, the upper or lower surface 5 or 6 of the multilayer body may be a mounting surface adjacent to a printed circuit board and facing the printed circuit board when the multilayer inductor is mounted on the printed circuit board.

The multilayer inductor 100 according to an exemplary embodiment in the present disclosure may implement high inductance while securing a sufficient space at the time of being mounted on a board due to an increase in the thickness of the multilayer body 110.

In the case in which the thickness of the multilayer body 110 is larger than the width thereof as in an exemplary embodiment in the present disclosure, it may be advantageous in that at the time of mounting the multilayer inductor on a board, although an area occupied by the multilayer inductor in the board is identical to that of a case in which the thickness of the multilayer body is smaller than the width thereof, high inductance may be secured. However, since the center of gravity of the multilayer inductor becomes raised, at the time of mounting the multilayer inductor on the board, a chip may be inclined in a taping pocket during a pick-up process, such that a defect that the chip is not picked-up may occur, or a phenomenon in which a chip topples over may frequently occur during a mounting process.

In addition, the phenomenon in which a chip topples over may occur when the multilayer inductor is mounted on the board or is subjected to a reflow process, or after the multilayer inductor is mounted on the board, or a mounting defect that the multilayer inductor rotates about an axis perpendicular to the board may occur. In the case in which the mounting defect occurs, a short-circuit may be caused due to contact with an electronic component disposed adjacent to the inductor.

According to an exemplary embodiment in the present disclosure, the internal coil part 120 is formed in the multilayer body 110 to be biased toward one portion thereof in the thickness direction, such that the above-mentioned defects may be solved. For example, the internal coil part 120 may be disposed to be biased downwardly of a central portion of the multilayer body 110 in the thickness direction so as to be adjacent to the lower surface 6 of the multilayer body.

Referring to FIG. 3, in the multilayer inductor 100 according to an exemplary embodiment in the present disclosure, the internal coil part 120 may be biased to be adjacent to the lower surface 6 of the multilayer body 110, such that a distance T_{T} between an upper portion of the internal coil part 120 and the upper surface 5 of the multilayer body may be longer than a distance T_{B} between a lower portion of the internal coil part and the lower surface 6 of the multilayer body.

In the case in which the internal coil part 120 is disposed in the multilayer body 110 to be biased toward the lower surface 6 of the multilayer body 110 as in an exemplary embodiment in the present disclosure, the internal coil part 120 having a relatively large weight as compared to the insulation layers 111 and 111′ may be adjacent to the lower surface 6 of the multilayer body 110, such that the center of gravity of the multilayer body 110 may be moved to be adjacent to the lower surface 6 of the multilayer body 110.

For example, a central portion C2 of the internal coil part 120 in the thickness direction may be disposed below a central portion C1 of the thickness of the multilayer body, such that the center of gravity of the multilayer body may be disposed below the central portion C1 of the multilayer body in the thickness direction.

According to an exemplary embodiment in the present disclosure, the internal coil part is formed in the multilayer body to be biased downwardly in the thickness direction, such that the center of gravity of the multilayer body may be moved downwardly as compared to the case in which the internal coil part is disposed at a central portion of the multilayer body in the thickness direction. Therefore, the mounting defect such as the phenomenon in which a chip topples over or the rotation of the chip occurring at the time of mounting the multilayer inductor on the board may be decreased, such that mounting stability may be improved.

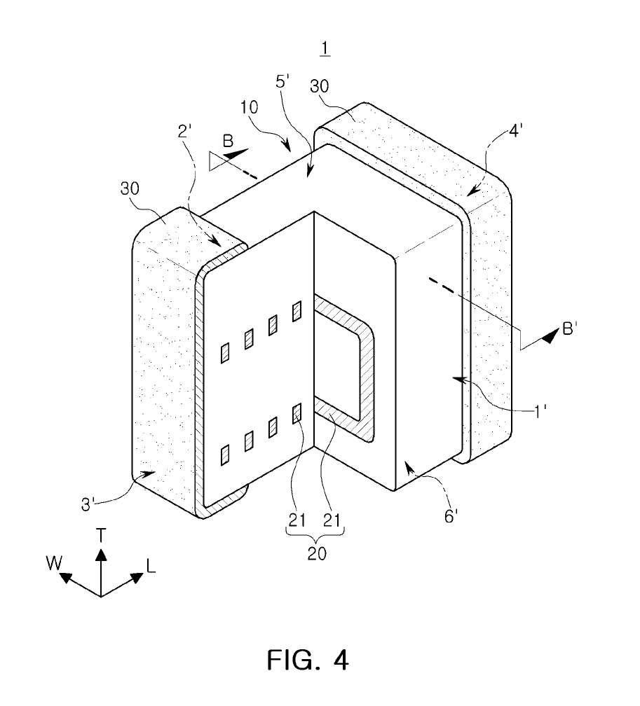

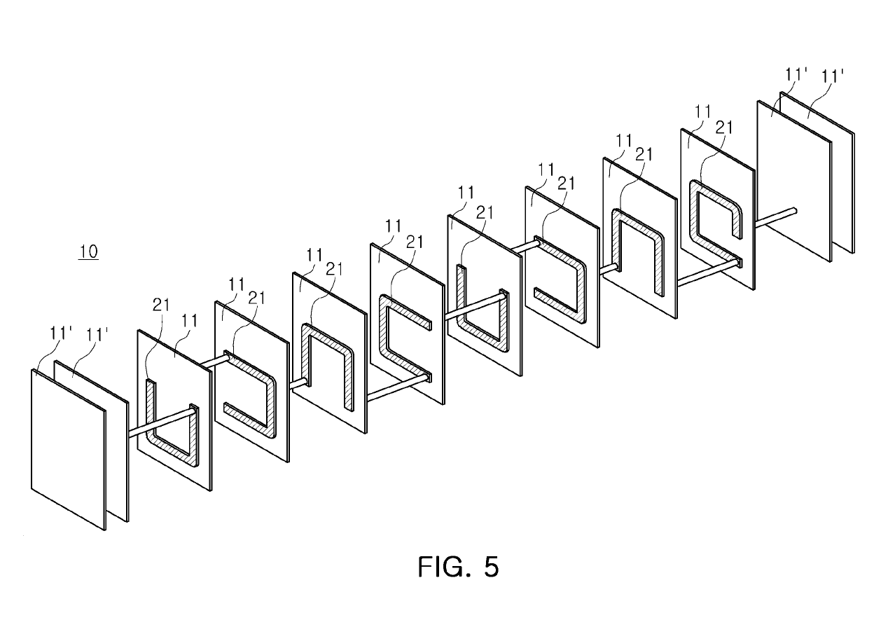

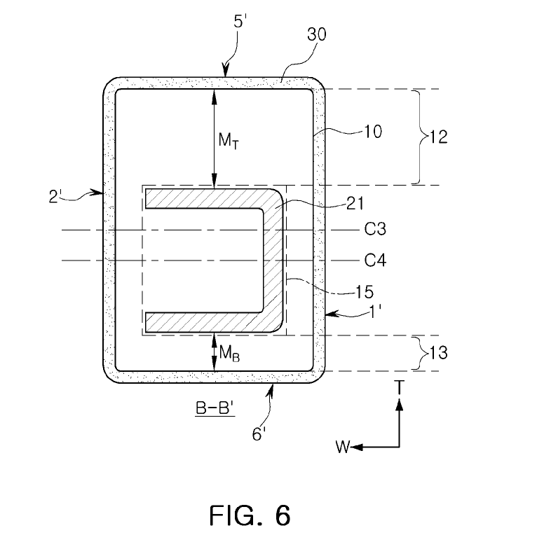

FIG. 4 is a perspective view showing a multilayer inductor 1 according to a modified example of an exemplary embodiment in the present disclosure. FIG. 5 is an exploded perspective view of a multilayer body 10, a component of the multilayer inductor 1 according to the modified example of FIG. 4. FIG. 6 is a cross-sectional view taken along line B-B′ of FIG. 4.

As shown in FIGS. 4 and 5, in the multilayer inductor 1 according to a modified example of an exemplary embodiment in the present disclosure, a stacking direction of the internal coil patterns 21 and the insulation layers 11 and 11′ may be a length direction of the multilayer body 10, unlike the above-mentioned multilayer inductor according to the foregoing exemplary embodiment in the present disclosure.

In the case of mounting the multilayer inductor 1 according to a modified example of the present disclosure on a board, the multilayer inductor 1 may have a vertical mounting type structure in which the internal coil patterns 21 are disposed to be substantially perpendicular with respect to the board.

According to a modified example of an exemplary embodiment in the present disclosure, an upper cover part 12 disposed on an upper portion of an active part 15 including an internal coil part 20 to form inductance in the thickness direction and a lower cover part 13 disposed on a lower portion of the active part 15 in the thickness direction may not be formed by stacking the insulation layers on which the internal coil patterns are not formed, but may be formed by stacking margin regions in which the internal coil patterns are not disposed on the insulation layers 11 on which the internal coil patterns 21 are formed.

According to another modified example of an exemplary embodiment in the present disclosure, the insulation layers 11′ on which the internal coil patterns are not formed may be disposed and stacked on one portion and the other portion of the active part 15 in the length direction.

In the multilayer inductor according to a modified example of an exemplary embodiment in the present disclosure, the internal coil patterns may be disposed on the insulation layers to be biased toward one portion of the multilayer body in the thickness direction.

Referring to FIG. 6, in a modified example of an exemplary embodiment in the present disclosure, a thickness M_{T} of the upper cover part 12 may be greater than a thickness M_{B} of the lower cover part 13.

In a modified example of an exemplary embodiment in the present disclosure, the thickness M_{T} of the upper cover part may be defined as a distance between an upper portion of the internal coil part and an upper surface of the multilayer body in thickness direction, and thickness M_{B} of the lower cover part may be defined as a distance between a lower portion of the internal coil part and a lower surface of the multilayer body in thickness direction.

According to a modified example of an exemplary embodiment in the present disclosure, a central portion of the internal coil part 20 in the thickness direction may be disposed below a central portion of the multilayer body 10 in the thickness direction, and the center of gravity of the multilayer body 10 may be disposed below the central portion of the multilayer body 10 in the thickness direction.

Since other features of the multilayer inductor according to the modified example are the same as those of the above-mentioned multilayer inductor according to an exemplary embodiment in the present disclosure, a detailed description thereof will be omitted.

A manufacturing method of a multilayer inductor according to an exemplary embodiment in the present disclosure may include preparing a plurality of magnetic sheets; forming internal coil patterns on the magnetic sheets; forming a sheet laminate by stacking the magnetic sheets; and forming a multilayer body by sintering the sheet laminate.

According to an exemplary embodiment in the present disclosure, may further include, after the forming of the multilayer body, forming an external electrode.

Hereinafter, a manufacturing method of a multilayer inductor according to an exemplary embodiment in the present disclosure will be described in detail, but is not limited thereto.

First, the plurality of magnetic sheets may be prepared. In all of the plurality of magnetic sheets, it may be unnecessary to differentiate sintering shrinkage rates, and two or more magnetic sheets may have the same sintering shrinkage rate as each other.

A magnetic material used to manufacture the magnetic sheet is not particularly limited. For example, a ferrite powder known in the art such as Mn—Zn based ferrite powder, Ni—Zn based ferrite powder, Ni—Zn—Cu based ferrite powder, Mn—Mg based ferrite powder, Ba based ferrite powder, Li based ferrite powder, or the like, may be used, but the present disclosure is not limited thereto.

The plurality of magnetic sheets may be prepared by applying slurry formed by mixing the magnetic material and an organic material onto carrier films and drying the same.

Then, the internal coil patterns may be formed on some of the plurality of magnetic sheets.

The internal coil patterns may be formed by applying a conductive paste containing a conductive metal onto the magnetic sheets using a printing method, or the like. As the printing method of the conductive paste, a screen printing method, a gravure printing method, or the like, may be used, but the present disclosure is not limited thereto.

The conductive metal is not particularly limited as long as the metal has excellent electrical conductivity. For example, as the conductive metal, silver (Ag), palladium (Pd), aluminum (Al), nickel (Ni), titanium (Ti), gold (Au), copper (Cu), platinum (Pt), or the like, may be used alone, or a mixture thereof may be used. In consideration of improving electrical conductivity and decreasing a manufacturing cost, most preferably, copper (Cu) may be used.

Next, the sheet laminate may be formed by stacking the magnetic sheets on which the internal coil patterns are formed and the magnetic sheets on which the internal coil patterns are not formed. Thereafter, the sheet laminate may be sintered, thereby forming the multilayer body.

At this time, in the case in which the sheet laminate formed by stacking the magnetic sheet containing ferrite is sintered under reduction atmosphere, since a magnetic property may be degraded due to reduction of the ferrite, the sintering may be performed under weak reduction atmosphere. A sintering temperature may be 850 to 1100□, but is not limited thereto.

Next, the external electrode connected to a lead-out portion of the internal coil part may be formed on an end surface of the sintered multilayer body.

The external electrode may be formed using a conductive paste containing a metal having excellent electrical conductivity, wherein the conductive paste may be a conductive paste containing, for example, one of nickel (Ni), copper (Cu), tin (Sn), and silver (Ag) or an alloy thereof. The external electrode may be formed by a dipping method, or the like, as well as a printed method according to a shape of the external electrode.

Board having Multilayer Inductor

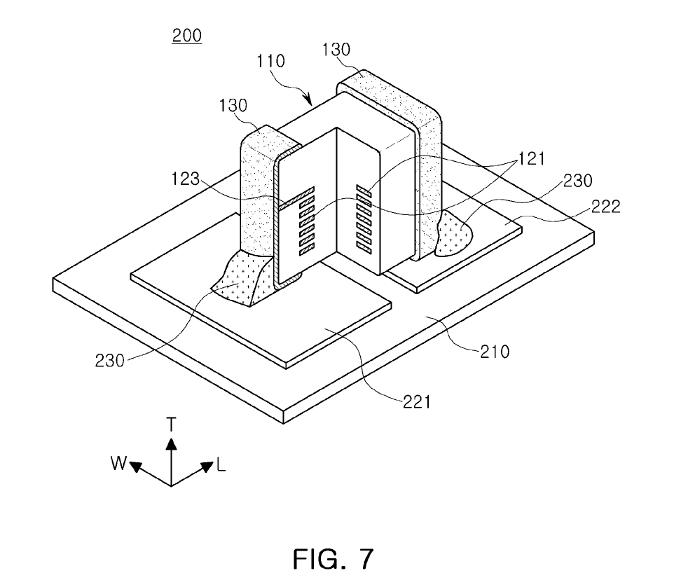

FIG. 7 is a perspective view schematically showing a board on which a multilayer inductor is mounted according to an exemplary embodiment in the present disclosure.

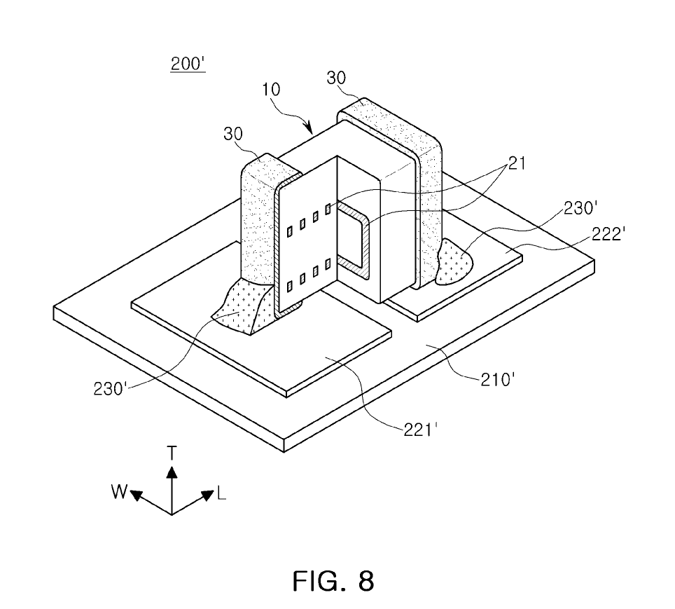

FIG. 8 is a perspective view showing a modified example of the board on which a multilayer inductor is mounted according to another exemplary embodiment in the present disclosure.

Referring to FIG. 7, the board 200 having a multilayer inductor according to the present exemplary embodiment may include the multilayer inductor 100 and a printed circuit board 210 on which the multilayer inductor 100 is mounted. The printed circuit board 210 may include electrode pads 221 and 222 formed on the printed circuit board 210.

The multilayer inductor 100 is the above-mentioned multilayer inductor according to an exemplary embodiment in the present disclosure, and hereinafter, a detailed description thereof will be omitted in order to avoid an overlapped description.

In the multilayer inductor according to the present exemplary embodiment, the internal coil patterns and the insulation layers may be disposed to be parallel to the printed circuit board.

The electrode pads 221 and 222 may be composed of first and second electrode pads 221 and 222 respectively connected to the external electrodes 130 of the multilayer inductor 100.

In this case, the external electrodes 130 of the multilayer inductor 100 may be electrically connected to the printed circuit board 210 by solder 230 in a state in which the external electrode 130 are positioned on the first and second electrode pads 221 and 222, respectively, to contact each other.

Referring to FIG. 8, the board 200′ having a multilayer inductor according to the modified example of the present disclosure may include the multilayer inductor 1 and a printed circuit board 210 on which the multilayer inductor 1 is mounted.

However, the multilayer inductor 1 may be the above-mentioned multilayer inductor according to the modified example of the present disclosure, and the internal coil patterns 21 may be disposed to be perpendicular with respect to the printed circuit board.

As shown in FIGS. 7 and 8, in the case in which the internal coil pattern is formed to be biased toward one portion of the multilayer body in the thickness direction so as to be adjacent to a mounting surface of the board as in an exemplary embodiment in the present disclosure, the center of gravity of the multilayer inductor may be moved to be adjacent to the printed circuit board, such that at the time of mounting the multilayer inductor on the board, mounting stability may be improved.

As set forth above, according to exemplary embodiments in the present disclosure, a multilayer inductor allowing for a decrease in a phenomenon in which a chip topples over at the time of the mounting of the multilayer inductor on a board and having excellent mounting stability, and a board having the same, may be provided.

While exemplary embodiments have been shown and described above, it will be apparent to those skilled in the art that modifications and variations could be made without departing from the spirit and scope of the present disclosure as defined by the appended claims.

What is claimed is:

1. A multilayer inductor comprising:
a multilayer body including a plurality of insulation layers stacked therein and having a thickness greater than a width thereof; and
an internal coil part disposed in the multilayer body, a plurality of internal coil patterns being electrically connected and disposed on the plurality of insulation layers,
wherein the internal coil part is disposed to be biased toward one portion of the multilayer body from a central portion of the multilayer body in a thickness direction.

2. The multilayer inductor of claim 1, wherein the multilayer body includes an active part including the internal coil part to form inductance, an upper cover part disposed on an upper portion of the active part in the thickness direction, and a lower cover part disposed on a lower portion of the active part in the thickness direction,
the upper cover part having a thickness greater than that of the lower cover part.

3. The multilayer inductor of claim 1, wherein a distance between an upper portion of the internal coil part and an upper surface of the multilayer body is longer than a distance between a lower portion of the internal coil part and a lower surface of the multilayer body.

4. The multilayer inductor of claim 1, wherein a central portion of the internal coil part in the thickness direction is disposed below the central portion of the multilayer body in the thickness direction.

5. The multilayer inductor of claim 1, wherein the center of gravity of the multilayer body is disposed below the central portion of the multilayer body in the thickness direction.

6. The multilayer inductor of claim 1, wherein the insulation layers and the internal coil patterns are stacked in the thickness direction of the multilayer body.

7. The multilayer inductor of claim 1, wherein the insulation layers and the internal coil patterns are stacked in a length direction of the multilayer body.

8. A board having a multilayer inductor, the board comprising:
a printed circuit board having first and second electrode pads formed thereon; and
a multilayer inductor mounted on the printed circuit board,
wherein the multilayer inductor includes a multilayer body including a plurality of insulation layers stacked therein and having a thickness larger than a width thereof; and an internal coil part disposed in the multilayer body, a plurality of internal coil patterns being electrically connected and disposed on the plurality of insulation layers, the internal coil part being disposed to be biased toward one portion of the multilayer body from a central portion of the multilayer body in a thickness direction.

9. The board of claim 8, wherein the multilayer body includes an active part including the internal coil part to form inductance, an upper cover part disposed on an upper portion of the active part in the thickness direction, and a lower cover part disposed on a lower portion of the active part in the thickness direction,
the upper cover part having a thickness greater than that of the lower cover part.

10. The board of claim 8, wherein a distance between an upper portion of the internal coil part and an upper surface of the multilayer body is longer than a distance between a lower portion of the internal coil part and a lower surface of the multilayer body.

11. The board of claim 8, wherein a central portion of the internal coil part in the thickness direction is disposed below the central portion of the multilayer body in the thickness direction.

12. The board of claim 8, wherein the center of gravity of the multilayer body is disposed below the central portion of the multilayer body in the thickness direction.

13. The board of claim 8, wherein the insulation layers and the internal coil patterns are stacked in the thickness direction of the multilayer body.

14. The board of claim 8, wherein the insulation layers and the internal coil patterns are stacked in a length direction of the multilayer body.
